(19) United States
(12) Patent Application Publication
(10) Pub. No.: US 2005/0095839 A1
(43) Pub. Date: May 5, 2005

(54) METHOD OF PATTERNING LOW-K FILM AND METHOD OF FABRICATING DUAL-DAMASCENE STRUCTURE

(76) Inventors: Ting-Chang Chang, Hsinchu (TW); Po-Tsun Liu, Hsinchu City (TW); Ya-Hsiang Tai, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/904,293

(22) Filed: Nov. 3, 2004

(30) Foreign Application Priority Data
Nov. 3, 2003 (TW) 92130680

(51) Int. Cl. H01L 21/311; H01L 21/00; H01L 21/302; H01L 21/4763; H01L 21/461

(52) U.S. Cl. 438/623; 438/624; 438/694; 438/745

(57) ABSTRACT

A method of patterning a low-k film is provided. In this method, a dielectric layer is spun over a substrate, and then an electron-beam exposure process is performed on the dielectric layer to define an exposed area and an unexposed area thereon. A developer is used to remove the unexposed area, wherein the developer can solve the unexposed area and enhance the porosity of the exposed area. Finally, a thermal process is performed on the exposed area.

### CROSS-REFERENCE TO RELATED APPLICATION

This application claims the priority benefit of Taiwan application serial no. 92130680, filed on Nov. 3, 2003.

### BACKGROUND OF THE INVENTION

1. Field of the Invention

The present invention relates to a method of forming a low-k film, and more particularly, to a method of patterning a low-k film and a method of forming a dual-damascene opening.

2. Description of the Related Art

In the present semiconductor technology, copper has the characteristics of low resistance and good electromigration, and can be formed by the electroplating method or the chemical vapor deposition (CVD) method, and is therefore widely used for interconnection in semiconductors. However, it is not an easy process to etch copper. Thus, a metal damascene process has replaced the conventional method for fabricating copper interconnectors in semiconductors.

As the dimensions of semiconductor devices have become minimized, resistance-capacitance (RC) time delay resulting from the multi-layer metal interconnection will substantially affect signal transmitting speeds. In the present technology, low-k material layers incorporated with copper lines have been used for improving device efficiency. If porous low-k films with low dielectric constants, such as less than 2.2, are used, RC time delay curbing the signal transmitting speeds can be reduced.

FIGS 1A-1D are schematic cross-sectional views showing progression of a conventional method of forming a via-first dual-damascene (VFDD) structure.

Referring to FIG. 1A, a substrate 100 is provided. Wherein, a conductive area 102 is formed on the substrate 100. A dielectric layer 104, an etching-stop layer 106 and a dielectric layer 108 are sequentially formed over the substrate 100, wherein at least one of the dielectric layers 104 and 108 is a porous low-k film.

Referring to FIG. 1B, a patterned photoresist layer 110 is formed over the dielectric layer 108 to define the via opening. By using the photoresist layer 110 as a mask, portions of the dielectric layer 108, the etching-stop layer 106 and the dielectric layer 104 are etched to form the via opening 112. A portion of the surface of the conductive area 102 is exposed under the bottom of the via opening 112.

Referring to FIG. 1C, the photoresist layer 110 is removed. The patterned photoresist layer 114 formed over the dielectric layer 108 is used to define trenches. By using the photoresist layer 114 as a mask, the etching process removes a portion of the dielectric layer 108 and the etching-stop layer 106 to form the trench 116. The trench 116 and the via opening 112 constitute the dual-damascene opening 118.

Referring to FIG. 1D, copper 120 is filled in the dual-damascene opening 118 to form the dual-damascene structure.

The dual-damascene structure, however, has the following disadvantages:

After the via opening 112 or the trench 116 is formed, a subsequent dry/wet cleaning method is used to remove the photoresist layer 110 or 114. The cleaning method is very likely to damage the sidewalls of the via opening 112 or the trench 116 and degrade the dielectric characteristics of the dielectric layers 104 and 108.

Moreover, moistures absorbed on the sidewalls of the dual-damascene opening 118, i.e. the dielectric opening 112 and the trench 116, may cause the surface of the conductive area 102 at the bottom of the dual-damascene opening 118 to oxidize, thus implicating the subsequent metal film deposition process. As a result, the adhesion of the metal film becomes weak and the resistance of the via and the conductive line will increase.

Moreover, the dual-damascene technology described above requires the etching-stop layer 106 in order to form a complete dual-damascene structure. The etching-stop layer 106, however, has a higher dielectric constant and this will increase the dielectric constant of the whole dielectric structure.

Though being explained in the VFDD technology, the disadvantage of increased dielectric constant also arises in the trench-first dual-damascene (TFDD) technology and the self-aligned dual-damascene (SADD) technology. Regarding the damage in the dielectric layers and moisture absorption on the sidewalls of the opening, these disadvantages will occur in any process of patterning the dielectric layer by a photolithography-etching process.

### SUMMARY OF THE INVENTION

Accordingly, the present invention is directed to a method of patterning a low-k film and a method of fabricating a dual-damascene structure. The present invention is capable of preventing damage on the sidewalls of the via opening or the trench in order to maintain the dielectric characteristics of the dielectric layer.

The present invention is also directed to a method of patterning a low-k film and a method of fabricating a dual-damascene structure. The present invention is capable of preventing moisture absorption on the sidewalls of the via opening or the trench in order to avoid increased resistance of the via and the conductive line.

The present invention is directed to a method of patterning a low-k film and a method of fabricating a dual-damascene structure in order to reduce the dielectric constant of the dielectric layer.

The present invention is directed to a method of fabricating a dual-damascene structure in order to fabricate the dual-damascene structure with a more simplified process, thereby reducing the manufacturing costs.

The present invention provides a method of patterning a low-k film. The method comprises spin-coating a dielectric layer over a substrate. An electron-beam exposure process is then performed on the dielectric layer to define an exposed area and an unexposed area thereon. Then the unexposed area is removed by using a developer, wherein the developer solves the unexposed area and enhances porosity of the exposed area. Finally, a thermal process is performed on the exposed area.

The present invention also provides a method of fabricating a dual-damascene structure. The method comprises providing a substrate, wherein a conductive area is formed on the substrate. A first dielectric layer is spin-coated over the substrate. A first electron-beam exposure process is then performed on the first dielectric layer to define a first exposed area and a first unexposed area thereon. The first unexposed area is removed by using a first developer to form a via opening in the remaining first exposed area, and expose a conductive area in the bottom of the via opening. Wherein, the first developer is able to solve the first unexposed area and enhance porosity of the first exposed area. Then a second dielectric layer is spin-coated over the substrate. A second electron-beam exposure process is performed on the second dielectric layer to define a second exposed area and a second unexposed area thereon. The second unexposed area is removed by using a second developer to form a trench in the remaining second exposed area, and the via opening and the trench constitutes a dual-damascene opening. Wherein, the second developer is able to solve the second unexposed area and enhances porosity of the second exposed area. A thermal process is then performed on the first exposed area and the second exposed area. Finally, a metal layer is filled in the dual-damascene opening.

In the method of patterning the low-k film and the method of fabricating the dual-damascene structure described above, materials of the dielectric layers, i.e. the first and the second dielectric layers, comprise a silsesquioxane-type low-k material or aromatic hydrocarbon. The silsesquioxane-type low-k material further comprises a material selected from a group consisting of hydrogen silsesquioxane (HSQ), methyl silsesquioxane (MSQ), hybrid-organic-siloxane-polymer (HOSP) and a porous silsesquioxane-type low-k material.

Accordingly, the present invention uses the electron beam to irradiate the uncured (sol-gel state) dielectric layer without using a photoresist layer. Therefore, degradation and damage of the dielectric layer when the photoresist layer is removed can be avoided, and the dielectric characteristics of the dielectric layer can be maintained.

In addition, the developer used in the development process of the present invention not only removes the dielectric layer not exposed to the electron beam, but enhances the porosity of the dielectric layer exposed to the electron beam. The process is able to reduce the dielectric constant of the subsequently formed dielectric layer.

Moreover, the present invention performs a thermal process on the patterned dielectric layer. Moisture absorbed in the dielectric layer can thus be removed and the degradation of the dielectric layer caused by moisture absorption thereon can be avoided. As a result, the mechanical characteristic of the dielectric layer is improved.

The present invention develops the unexposed dielectric layer to pattern the dielectric layer after the electron-beam exposure. Without using the conventional, complex photolithography and etch processes, the present invention is able to simplify the fabrication process and reduce the manufacturing costs.

Due to the high resolution, such as about 10-20 nm, of the electron-beam exposure process, the present invention can be applied in the nanometer-dimension semiconductor fabrication technology.

In the method of fabricating the dual-damascene structure of the present invention, at least one etching-stop layer, disposed between the dielectric layer in which the via opening is formed and the dielectric layer in which the trench is formed, can be left out. Accordingly, the whole dielectric constant of the dielectric layers in the present invention can be reduced.

The above and other features of the present invention will be better understood from the following detailed description of the embodiments of the invention that is provided in conjunction with the accompanying drawings.

### BRIEF DESCRIPTION OF THE DRAWINGS

FIGS 1A-1D are schematic cross-sectional views showing progression of a conventional method of forming a via-first dual-damascene (VFDD) structure.

FIGS. 2A-2C are schematic cross-sectional views showing progression of a method of patterning a low-k film according to a first embodiment of the present invention.

FIGS. 3A-3E are schematic cross-sectional views showing progression of a method of fabricating a dual-damascene structure according to a second embodiment of the present invention.

FIG. 4 is a scanning electron microscopy (SEM) picture of the porous low-k film with line width of 60 nm formed according to the present invention.

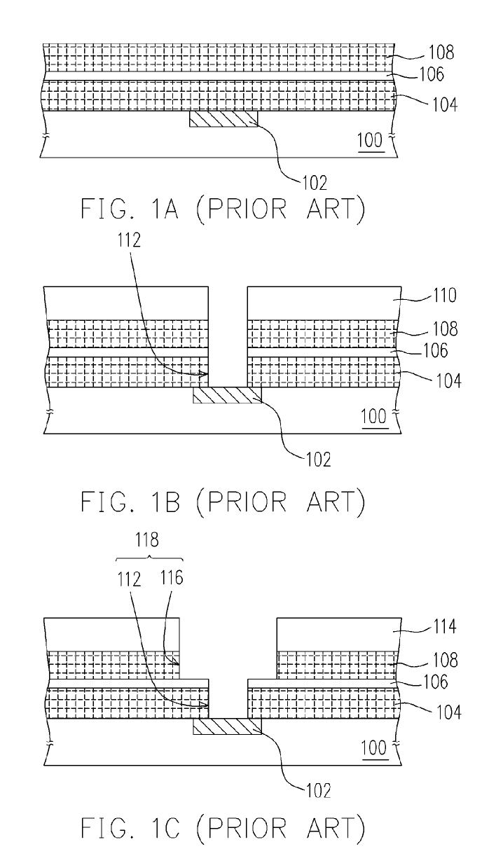

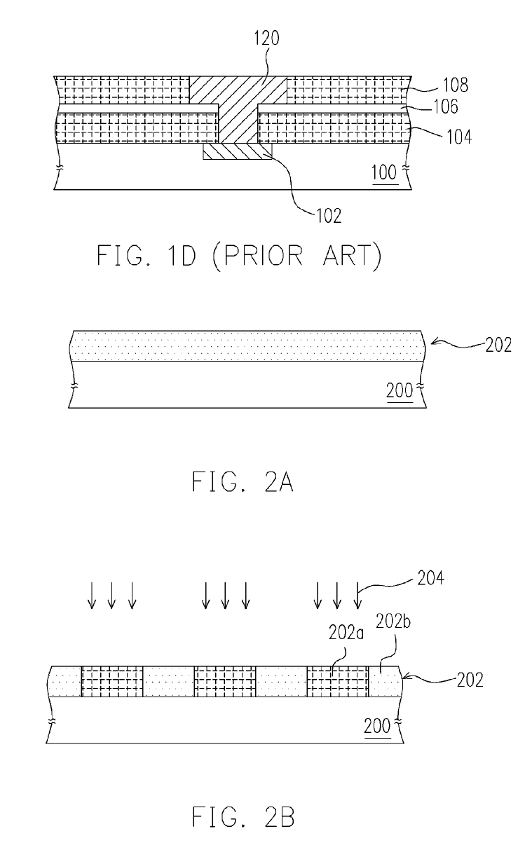

### DESCRIPTION OF THE EMBODIMENTS

The First Embodiment: Patterning a low-k film

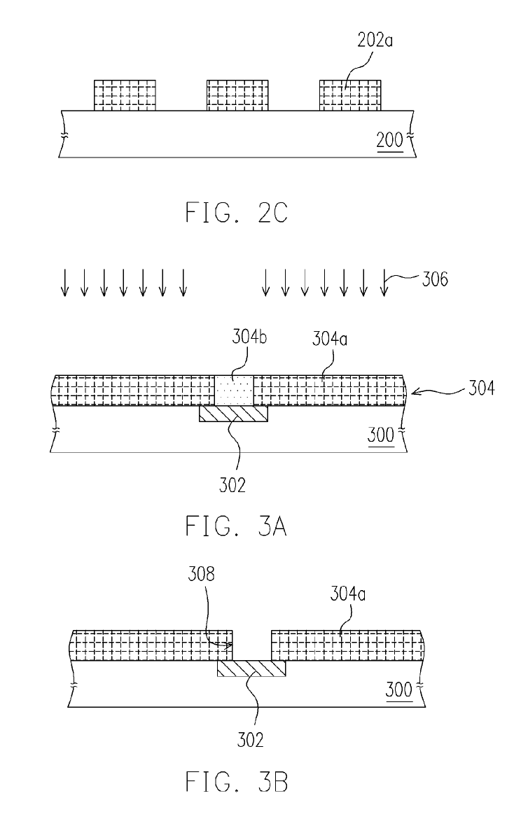

FIGS. 2A-2C are schematic cross-sectional views showing progression of a method of patterning a low-k film according to a first embodiment of the present invention.

Referring to FIG. 2A, a substrate 200 is provided. A dielectric layer 202 is formed over the substrate 200. In this embodiment, the substrate 200 can be made of, for example, a single crystal silicon material. In addition, the substrate 200 can also be made of, for example, GaN, GaAs or a material suitable for making semiconductors.

The material of the dielectric layer 202 can be, for example, a spin-on low-k material, wherein the spin-on low-k layer can be, for example, a silsesquioxane-type low-k material or aromatic hydrocarbon. The silsesquioxane-type low-k material can be, for example, hydrogen silsesquioxane (HSQ), methyl silsesquioxane (MSQ), hybrid-organic-siloxane-polymer (HOSP) or a porous silsesquioxane-type low-k material. The aromatic hydrocarbon can be, for example, SiLK (a registered trademark), benzocyclobutene (BCB), FLARE (a registered trademark), polyarylene ether (PAE-2) (registered trademark), fluoro-polyimide or polyaryl ether.

The method of forming the dielectric layer 202 comprises, for example, spin-coating the spin-on low-k material over the substrate 200. In this embodiment, the spin-on low-k material is preferably the porous silsesquioxane-type low-k material, which can be, for example, the silsesquioxane low-k material with the foaming agent, which is a solution. The components of the foaming agent is selected from a group consisting of polycaprolactone (PCL), poly propylene oxide (PPO), polymethylmethylacrylate (PMMA), polyester, and polycarbonate. Additionally, the componants of the foaming agent have the characteristic of low-temperature decomposition at a temperature about 250° C.

Note that in this embodiment, the dielectric layer 202 is merely spin-coated over the substrate 200 before curing. That is, the dielectric layer 202 is in a sol-gel state.

Referring to FIG. 2B, an electron-beam exposure process 204 is performed on the dielectric layer 202 to define the exposed area 202a and the unexposed area 202b thereon. The energy of the electron beam is from about 5 μC/cm² to about 80 μC/cm². The exposed area 202a is cured by the energy of the electron beam. The energy creates cross-linking in the film structure of the exposed area 202a. The unexposed area 202b not exposed to the electron beam is still in the gel-sol state.

In this step, it should be noted that the area and the pattern to be irradiated by the electron beam can be determined, for example, by a computer program. Accordingly, a photoresist process is not required in this step and the pattern can be formed on the dielectric layer 202 by using the electron beam to irradiate the dielectric layer 202.

Referring to FIG. 2C, the unexposed area 202b not irradiated by the electron beam is removed by using a developer. The exposed area 202a thus remains over the substrate 200. Wherein, the developer can solve the unexposed area 202b. In addition to solving the dielectric layer of the unexposed area 202b, the developer, preferably, can enhance the porosity of the exposed area 202a. In this embodiment, if the material of the dielectric material 202 is the porous silsesquioxane-type low-k material, the material of the developer can be, for example, a tetramethyl ammonium hydroxide ((CH₃)₄NOH, TMAH) solution, a methyl isobutyl ketone (MIBK) solution, a dibutylether (DBE) solution or a PBMEA solution. Wherein, the method of preparing the the THMA solution comprises mixing THMA and water with a proportion of 10%:90%, and then pouring the mixture into the methanol (CH₃OH) with 99.99% purity.

If the material of the dielectric material 202 is the aromatic hydrocarbon, the developer corresponding thereto can be, for example, a mesitylene solution, a cyclohexanone solution or a butyrolactone solution.

Then a thermal process is performed on the substrate 200 with the exposed area 202a formed thereon. The thermal process is able to remove the moisture absorbed in the dielectric layer 202, decompose the foaming agent and enhance the thin film bonding strength of the exposed area 202a. Wherein, the thermal process comprises, for example, disposing the substrate 200 in a furnace with a temperature from about 300° C. to about 400° C. for about 30 minutes to about 60 minutes. Finally, the porous patterned thin film, i.e. the exposed area 202a, with the low dielectric constant of about 1.85 is obtained.

In the dielectric layer 202 made of the same spin-on low-k material in the prior art, the dielectric layer, which is cured immediately after the spin-on process, has a dielectric constant of about 2.1. The dielectric constant may increase in the subsequent photolithography-etching process. Compared with the conventional dielectric layer, the patterned dielectric layer of the present invention has a dielectric constant of about 1.85. Accordingly, with the same spin-on low-k material, the dielectric layer formed in the present invention has lower constant than that of the conventional method.

In addition to the patterned low-k film, the present invention can be further applied in fabricating a copper dual-damascene structure.

The Second Embodiment: Fabricating a Dual-Damascene Structure

The following is a description of a method of fabricating a dual-damascene structure.

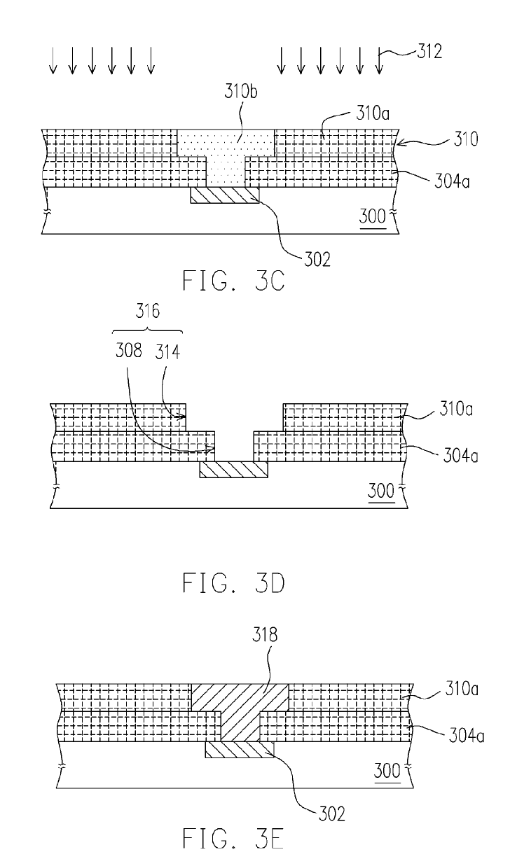

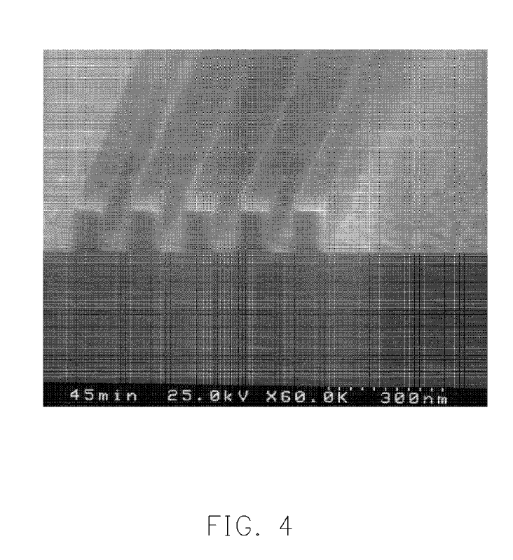

FIGS. 3A-3D are schematic cross-sectional views showing progression of a method of fabricating a dual-damascene structure according to a second embodiment of the present invention. In this embodiment, the method of forming the dielectric layer, the material of the dielectric layer and the method of forming the pattern are similar to those described in the first embodiment. Detailed descriptions are not repeated.

First, referring to FIG. 3A, a substrate 300 is provided. A conductive area 302 is formed on the substrate 300. A dielectric layer 304 is formed over the substrate 300. In this embodiment, the method of forming the dielectric layer 304 and the material of the dielectric layer 304 are similar to those of the dielectric layer 202 described in the first embodiment.

Referring to FIG. 3A, an electron-beam exposure process 306 is performed on the dielectric layer 304 to define the exposed area 304a and the unexposed area 304b. In this embodiment, the electron-beam exposure process 306 is similar to the electron-beam exposure process 204 of the first embodiment.

Referring to FIG. 3B, the unexposed area 304b is removed by using a developer so as to form a via opening 308 over the substrate 300. The bottom of the via opening 308 exposes a portion of the conductive area 302. In this embodiment, the developer used to removing the unexposed area 304b is similar to the developer used to remove the unexposed area 202b described in the first embodiment.

Referring to FIG. 3C, a dielectric layer 310 is formed over the substrate 300, covering the exposed area 304a and the via opening 308. In this embodiment, the method of forming the dielectric layer 310 and the material of the dielectric layer 310 can be similar to those of the dielectric layer 202 described in the first embodiment.

Referring to FIG. 3C, an electron-beam exposure process 312 is performed on the dielectric layer 310 to define the exposed area 310a and the unexposed area 310b. Wherein, the electron-beam exposure process 312 is similar to the electron-beam exposure process 204 of the first embodiment.

Referring to FIG. 3D, the unexposed area 310b is removed by using a developer to form a dual-damascene opening 316 constituted by the via opening 308 and the trench 314. In this embodiment, the developer used to remove the unexposed area 310b is similar to that used to remove the unexposed area 202b described in the first embodiment.

Then a thermal process is performed on the substrate 200 with the dual-damascene opening 316. The thermal process is able to remove the moisture absorbed in the dielectric layers 304 and 310, decompose the foaming agent and enhances the thin film bonding strength of the exposed areas 304a and 310a. In this embodiment, the thermal process is similar to that described in the first embodiment. Finally, the dielectric layers, i.e. the exposed areas 304a and 310a, with the dual-damascene opening 316 and with low dielectric constant of about 1.85 is produced.

Finally, referring to FIG. 3E, the metal layer 318 is filled in the dual-damascene opening 316 to form the dual-damascene structure. Wherein, the method of forming the dual-damascene structure comprises, for example, forming a metal material layer (not shown) over the substrate 300 and filling the dual-damascene opening 316 with the metal material. Wherein, the material of the metal material layer can be, for example, copper. The metal material layer outside the dual-damascene opening 316 is then removed to form the metal layer 318.

FIG. 4 is a scanning electron microscopy (SEM) picture of the porous low-k film with line width of 60 nm formed according to the present invention. From FIG. 4, it can be observed that the method of the present invention is able to form the patterned porous low-k film with high resolution and sharp profiles.

Accordingly, the present invention has at least the following advantages:

1. In the method of patterning the low-k film and the method of fabricating the dual-damascene structure, the present invention uses the electron beam to irradiate the uncured (sol-gel state) dielectric layer without using a photoresist layer. Therefore, degradation and damage of the dielectric layer which occur during the step of removing the photoresist layer can be avoided. As a result, the dielectric characteristics of the dielectric layer can be maintained.

2. In the method of patterning the low-k film and the method of fabricating the dual-damascene structure, the developer used in the development process of the present invention can not only remove the dielectric layer not exposed by the electron beam, but enhance the porosity of the dielectric layer exposed to the electron beam. The process can further reduce the dielectric constant of the subsequently formed dielectric layer.

3. In the method of patterning the low-k film and the method of fabricating the dual-damascene structure in the present invention, a thermal process is performed on the patterned dielectric layer. Thus, moisture absorbed in the dielectric layer can be removed and the degradation of the dielectric layer caused by moisture absorption can be avoided. As a result, the mechanical characteristic of the dielectric layer is improved.

4. In the method of patterning the low-k film and the method of fabricating the dual-damascene structure in the present invention, the unexposed dielectric layer is developed to pattern the dielectric layer after the electron-beam exposure. Without using conventional, complex photolithography and etching process, the present invention is able to simplify the fabrication process and reduce the manufacturing costs.

5. By using the same spin-on low-k material, the method of the present invention is able to generate a dielectric layer with lower constant than that formed by the conventional method.

6. In the method of patterning the low-k film and the method of fabricating the dual-damascene structure, due to the high resolution, such as about 10-20 nm, of the electron-beam exposure, the present invention can be applied to the nanometer-dimension semiconductor fabrication technology.

7. In the method of fabricating the dual-damascene structure, at least one etching-stop layer, disposed between the dielectric layer in which the via opening is formed and the dielectric layer in which the trench is formed, can be saved. Accordingly, the whole dielectric constant of the dielectric layers of the present invention can be reduced.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

1. A method of patterning a low-k film, comprising:
spin-coating a dielectric layer over a substrate;
performing an electron-beam exposure process on the dielectric layer to define an exposed area and an unexposed area in the dielectric layer;
removing the unexposed area by using a developer, wherein the developer is capable of solving the unexposed area and enhancing porosity of the exposed area; and
performing a thermal process on the exposed area.

2. The method of patterning the low-k film of claim 1, wherein a material of the dielectric layer comprises a spin-on low-k material.

3. The method of patterning the low-k film of claim 1, wherein a material of the dielectric layer comprises a silsesquioxane-type low-k material or an aromatic hydrocarbon.

4. The method of patterning the low-k film of claim 3, wherein the silsesquioxane-type low-k material comprises a hydrogen silsesquioxane (HSQ), a methyl silsesquioxane (MSQ), a hybrid-organic-siloxane-polymer (HOSP) or a porous silsesquioxane-type low-k material.

5. The method of patterning the low-k film of claim 4, wherein the porous silsesquioxane-type low-k material comprises a silsesquioxane-type low-k material with a foaming agent.

6. The method of patterning the low-k film of claim 5, wherein the foaming agent comprises a polycaprolactone (PCL), a poly propylene oxide (PPO), a polymethylmethylacrylate (PMMA), a polyester, or a polycarbonate.

7. The method of patterning the low-k film of claim 1, wherein after the step of spinning the dielectric layer, and before the step of performing the electron-beam exposure process, the dielectric layer is in a sol-gel state.

8. The method of patterning the low-k film of claim 1, wherein an energy of the electron-beam exposure is from about 5 μC/cm² to about 80 μC/cm².

9. The method of patterning the low-k film of claim 1, wherein the developer comprises a tetramethyl ammonium hydroxide ((CH₃)₄NOH, TMAH) solution, a methyl isobutyl ketone (MIBK) solution or a dibutylether (DBE) solution.

10. The method of patterning the low-k film of claim 9, wherein a methanol solution of the THMA solution is formed by mixing THMA and water with a proportion of 10%:90%, and then pouring the mixture in a methanol with 99.99% purity.

11. The method of patterning the low-k film of claim 1, wherein the developer comprises a mesitylene solution, a cyclohexaneone solution or a butyrolactone solution.

12. The method of patterning the low-k film of claim 1, wherein the thermal process comprises disposing the substrate in a furnace with a temperature from about 300° C. to about 400° C. for about 30 minutes to about 60 minutes.

13. A method of fabricating a dual-damascene structure, comprising:
providing a substrate, wherein a conductive area is formed over the substrate;
spin-coating a first dielectric layer over the substrate;
performing a first electron-beam exposure process on the first dielectric layer to define a first exposed area and a first unexposed area in the first dielectric layer;
removing the first unexposed area by using a first developer to form a via opening in the remaining first exposed area, a bottom of the via opening exposing the conductive area, wherein the first developer is capable of solving the first unexposed area and enhancing porosity of the first exposed area;
spin-coating a second dielectric layer over the substrate;
performing a second electron-beam exposure process on the second dielectric layer to define a second exposed area and a second unexposed area in the second dielectric layer;
removing the second unexposed area by using a second developer to form a trench in the remaining second exposed area, the via opening and the trench constituting a dual-damascene opening, wherein the second developer is capable of solving the second unexposed area and enhancing porosity of the second exposed area;
performing a thermal process on the first exposed area and the second exposed area; and
filling a metal layer in the dual-damascene opening.

14. The method of fabricating the dual-damascene structure of claim 13, wherein a material of the first dielectric layer comprises a spin-on low-k material.

15. The method of fabricating the dual-damascene structure of claim 13, wherein a material of the first dielectric layer comprises a silsesquioxane-type low-k material or an aromatic hydrocarbon.

16. The method of fabricating the dual-damascene structure of claim 15, wherein the silsesquioxane-type low-k material comprises a hydrogen silsesquioxane (HSQ), a methyl silsesquioxane (MSQ), a hybrid-organic-siloxane-polymer (HOSP) or a porous silsesquioxane-type low-k material.

17. The method of fabricating the dual-damascene structure of claim 16, wherein the porous silsesquioxane-type low-k material comprises a silsesquioxane-type low-k material with a foaming agent.

18. The method of fabricating the dual-damascene structure of claim 17, wherein the foaming agent comprises a polycaprolactone (PCL), a poly propylene oxide (PPO), a polymethyl methylacrylate (PM MA), a polyester, or a polycarbonate.

19. The method of fabricating the dual-damascene structure of claim 13, wherein after the step of spinning the first dielectric layer, and before the step of performing the first electron-beam exposure process on the first dielectric layer, the first dielectric layer is in a sol-gel state.

20. The method of fabricating the dual-damascene structure of claim 13, wherein an energy of the first electron-beam exposure is from about 5 μC/cm² to about 80 μC/cm².

21. The method of fabricating the dual-damascene structure of claim 13, wherein the first developer comprises a tetramethyl ammonium hydroxide ((CH₃)₄NOH, TMAH) solution, a methyl isobutyl ketone (MIBK) solution or a dibutylether (DBE) solution.

22. The method of fabricating the dual-damascene structure of claim 21, wherein a methanol solution of the THMA solution is formed by mixing THMA and water with a proportion of 10%:90%, and then pouring the mixture in a methanol with 99.99% purity.

23. The method of fabricating the dual-damascene structure of claim 13, wherein the first developer comprises a mesitylene solution, a cyclohexaneone solution or a butyrolactone solution.

24. The method of fabricating the dual-damascene structure of claim 13, wherein a material of the second dielectric layer comprises a spin-on low-k material.

25. The method of fabricating the dual-damascene structure of claim 13, wherein a material of the second dielectric layer comprises a silsesquioxane-type low-k material or an aromatic hydrocarbon.

26. The method of fabricating the dual-damascene structure of claim 25, wherein the silsesquioxane-type low-k material comprises a hydrogen silsesquioxane (HSQ), a methyl silsesquioxane (MSQ), a hybrid-organic-siloxane-polymer (HOSP) or a porous silsesquioxane-type low-k material.

27. The method of fabricating the dual-damascene structure of claim 26, wherein the porous silsesquioxane-type low-k material comprises a silsesquioxane-type low-k material with a foaming agent.

28. The method of fabricating the dual-damascene structure of claim 27, wherein the foaming agent comprises a polycaprolactone (PCL), a poly propylene oxide (PPO), a polymethylmethylacrylate (PMMA), a polyester, or a polycarbonate.

29. The method of fabricating the dual-damascene structure of claim 13, wherein after the step of spinning the second dielectric layer, and before the step of performing the second electron-beam exposure process on the second dielectric layer, the second dielectric layer is in a sol-gel state.

30. The method of fabricating the dual-damascene structure of claim 13, wherein an energy of the second electron-beam exposure is from about 5 μC/cm² to about 80 μC/cm².

31. The method of fabricating the dual-damascene structure of claim 13, wherein the second developer comprises a tetramethyl ammonium hydroxide ((CH₃)₄NOH, TMAH) solution, a methyl isobutyl ketone (MIBK) solution or a dibutylether (DBE) solution.

32. The method of fabricating the dual-damascene structure of claim 31, wherein a methanol solution of the THMA solution is formed by mixing THMA and water with a proportion of 10%:90%, and then pouring the mixture in a methanol with 99.99% purity.

33. The method of fabricating the dual-damascene structure of claim 13, wherein the second developer comprises a mesitylene solution, a cyclohexaneone solution or a butyrolactone solution.

34. The method of fabricating the dual-damascene structure of claim 13, wherein the thermal process comprises disposing the substrate in a furnace with a temperature from about 300° C. to about 400° C. for about 30 minutes to about 60 minutes.
